(19) United States
(12) Patent Application Publication
(10) Pub. No.: US 2025/0316568 A1
(43) Pub. Date: Oct. 9, 2025

(54) ELECTRONIC DEVICE AND METHOD OF MANUFACTURING THE SAME

(71) Applicant: InnoLux Corporation, Miao-Li County (TW)

(72) Inventors: Po-Yun HSU, Miao-Li County (TW); Ju-Li WANG, Miao-Li County (TW); Chia-Ping TSENG, Miao-Li County (TW)

(21) Appl. No.: 19/074,805

(22) Filed: Mar. 10, 2025

Related U.S. Application Data
(60) Provisional application No. 63/575,867, filed on Apr. 8, 2024.

(30) Foreign Application Priority Data
Sep. 20, 2024 (CN) 202411316045.X

(51) Int. Cl. H01L 23/498; G02B 6/12; H01L 21/48; H01L 21/56; H01L 23/00; H01L 23/31; H01L 23/538; H01L 25/065; H01L 25/16; H01L 25/18; H10D 80/30

(52) U.S. Cl. CPC H01L 23/49816; H01L 21/4853; H01L 21/4857; H01L 21/486; H01L 21/561; H01L 23/3135; H01L 23/49822; H01L 23/49838; H01L 23/5383; H01L 23/5385; H01L 23/5386; H01L 24/20; H01L 24/24; H01L 24/96; H01L 24/97; H01L 25/0652; H01L 25/16; H01L 25/18; G02B 6/12; H01L 24/16; H01L 24/32; H01L 24/73; H01L 2224/16227; H01L 2224/16238; H01L 2224/2101; H01L 2224/2105; H01L 2224/24146; H01L 2224/244; H01L 2224/32225; H01L 2224/73204; H01L 2224/95001; H01L 2224/96; H01L 2224/97; H01L 2924/37001; H10D 80/30

(57) ABSTRACT

A method of manufacturing an electronic device is provided. The method includes the following steps: providing a substrate; forming a circuit structure on the substrate; forming a hole in the substrate; forming a conductive element in the hole; bonding a chip to the circuit structure; and performing a first cutting step to cut a portion of the circuit structure and the substrate, and forming a groove in the substrate.

### CROSS REFERENCE TO RELATED APPLICATIONS

This application claims the benefit of China Application No. 202411316045.X, filed Sep. 20, 2024, which claims the benefit of provisional Application No. 63/575,867 filed September Apr. 8, 2024, the entirety of which are incorporated by reference herein.

### BACKGROUND

### Technical Field

The present disclosure is related to an electronic device and a method of manufacturing the same, and in particular it is related to a packaging structure of an electronic device and a method of manufacturing the same.

### Description of the Related Art

Packaging technology can increase the integration density of electronic components (e.g., transistors, diodes, resistors, capacitors, etc.) in a given area, and has been widely used in the production and manufacturing of electronic devices in recent years. As the packaging size of semiconductors becomes smaller, the reliability requirements for chip manufacturing and packaging technology are increasing.

2.5D or 3D advanced packaging technology using three-dimensional packaging stacks the chips and then packages them on the substrate, thereby reducing the area occupied by the chips. This reduces the costs and energy consumption of driving the chips. Electronic components formed using three-dimensional packaging technology usually have an interposer substrate. An interposer substrate with through holes can provide a shorter signal transmission path, improving the electrical performance of the electronic device or the flexibility of the stacking design. However, the technology used for forming good quality vias in interposer substrates is not yet mature.

Based on the above, developing structural and process designs that can improve the packaging yield of electronic devices is still one of the current research topics in the industry.

### SUMMARY

In accordance with some embodiments of the present disclosure, a method of manufacturing an electronic device is provided. The method includes the following steps: providing a substrate; forming a circuit structure on the substrate; forming a hole in the substrate; forming a conductive element in the hole; bonding a chip to the circuit structure; and performing a first cutting step to cut a portion of the circuit structure and the substrate, and forming a groove in the substrate.

In accordance with some other embodiments of the present disclosure, an electronic device is provided. The electronic device includes a substrate, a through hole, a protective layer, a conductive element, a circuit structure, a chip, and an encapsulation layer. The through hole penetrates the substrate. The protective layer is disposed on the substrate and extends into the through hole. The conductive element is disposed in the through hole. The circuit structure is disposed on the protective layer, and the circuit structure is electrically connected to the conductive element. The chip is bonded to the circuit structure. The encapsulation layer surrounds the chip. Moreover, the substrate has a recessed profile at an edge, and the encapsulation layer extends into the recessed profile.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A to 1D are cross-sectional diagrams of an electronic device in different stages of the manufacturing process in accordance with some embodiments of the present disclosure;

FIGS. 2A to 2H are cross-sectional diagrams of an electronic device in different stages of the manufacturing process in accordance with some embodiments of the present disclosure;

FIG. 3 is a cross-sectional diagram of an electronic device in accordance with some embodiments of the present disclosure;

FIG. 4 is a cross-sectional diagram of an electronic device in accordance with some embodiments of the present disclosure;

FIG. 5 is a cross-sectional diagram of an electronic device in accordance with some embodiments of the present disclosure;

FIG. 6 is a cross-sectional diagram of an electronic device in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, a scanning electron microscope (SEM), an optical microscope (OM), a film thickness profiler (α-step), an ellipsometer or another suitable method may be used to measure the width, thickness or height of each element, or spacing or distance between elements. Specifically, in accordance with some embodiments, a scanning electron microscope may be used to obtain a cross-sectional image including the elements to be measured, and the width, thickness or height of each element, or spacing or distance between elements in the image can be measured.

According to the present disclosure, the roughened surface refers to a distance difference between 0.15 μm and 1 μm between the peaks and valleys of the surface undulations when observed with a scanning electron microscope (SEM). The roughness can be determined by using a SEM or a transmission electron microscope (TEM) to observe the surface undulations at appropriate magnification. In addition, the surface undulating conditions are compared in a unit length (for example, 10 μm). Herein, “appropriate magnification” means that at least 10 undulating peaks and valleys can be observed on at least one surface under this magnification. In addition, according to embodiments of the present disclosure, roughness can be expressed by arithmetic average roughness (Ra) or maximum peak-to-valley height (Rz).

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, the method of manufacturing an electronic device provided can improve the process yield of forming through holes in a substrate (for example, an interposer substrate). For example, the structural strength of the substrate and the quality of the electrical connection between the circuit and the conductive elements, etc. can be improved during the process. The reliability and overall performance of the packaging structure of the electronic device thereby can be improved.

In accordance with the embodiments of the present disclosure, the electronic device can be applied to a power module, a semiconductor packaging device, a display device, a light-emitting device, a backlight device, an antenna device, a touch device, a sensing device, a wearable device, an automotive device, a battery device or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, other suitable materials, or a combination thereof. The electronic device may include electronic components, and the electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro-light-emitting diode (micro LED) or a quantum dot light-emitting diode (QD LED), but it is not limited thereto. In accordance with some embodiments, the electronic device may include a panel and/or a backlight module. The panel may include, for example, a liquid-crystal panel or other self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

In accordance with the embodiments of the present disclosure, the method of manufacturing the electronic device provided can be applied, for example, to a wafer-level package (WLP) or panel-level package (PLP) process, and the chip first process or the chip last/RDL first process can be used, which will be explained in further detail below.

Moreover, in accordance with the embodiments of the present disclosure, the packaging structure of the electronic device may include a system on package (SoC), a system in package (SiP), a chip on wafer on substrate (CoWoS) package, a system on integrated chip (SoIC) package, an antenna in package (AiP), a co-packaged optics (COP), a micro electro mechanical system (MEMS) or a combination thereof, but it is not limited thereto.

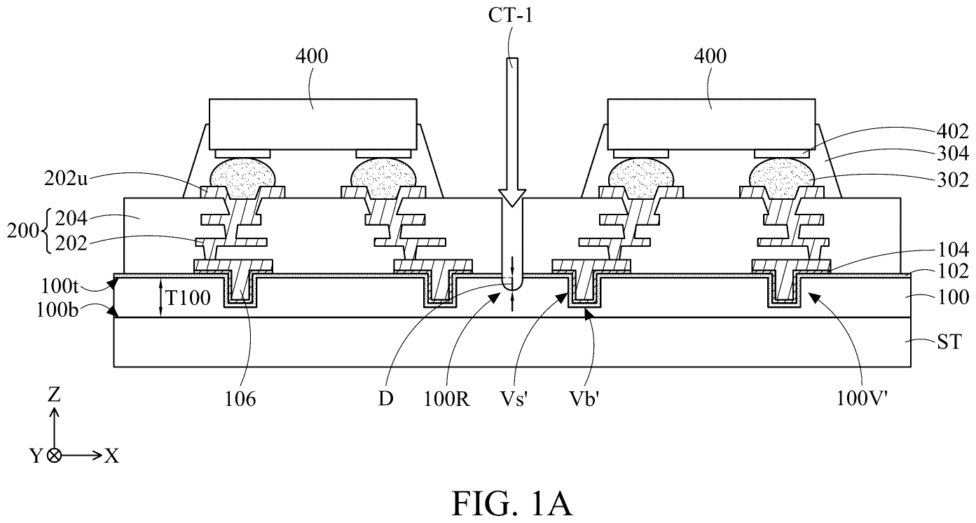

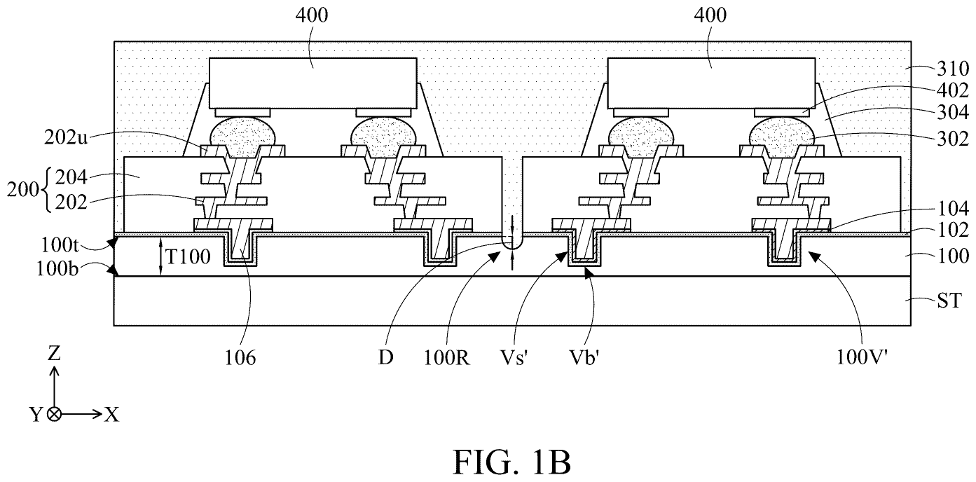

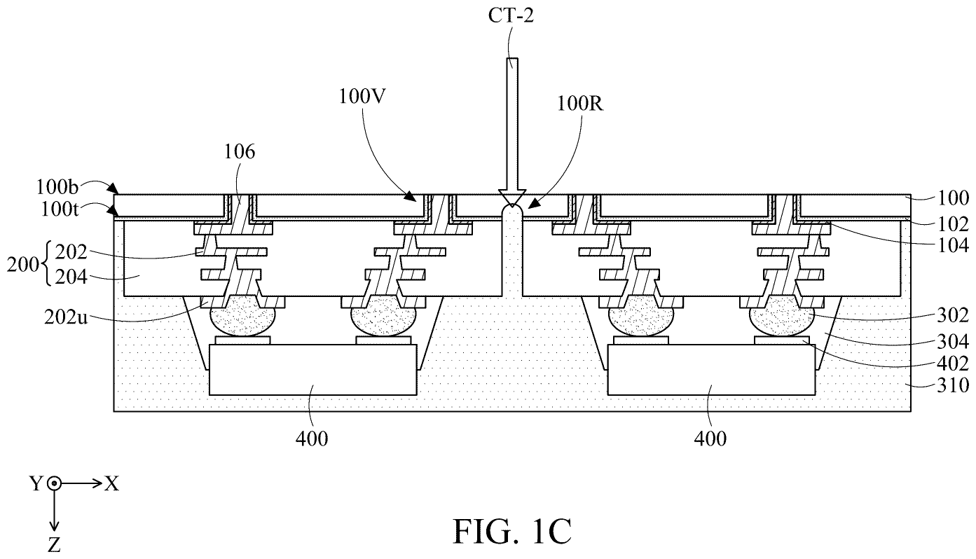

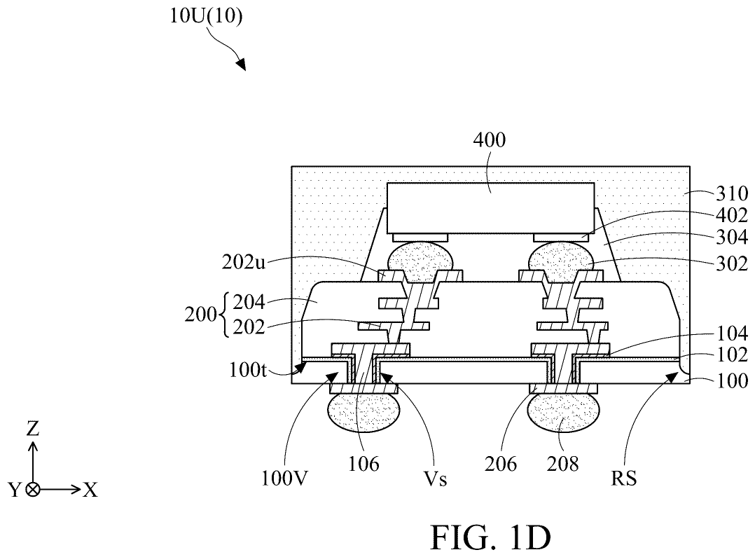

Please refer to FIGS. 1A to 1D, which are cross-sectional diagrams of an electronic device 10 in different stages of the manufacturing process in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below. In addition, it should be understood that, in accordance with some embodiments, additional operating steps may be provided before, during, and/or after the method of manufacturing the electronic device 10. In accordance with some embodiments, some of the operating steps described may be replaced or omitted, and the order of some of the operation steps described may be interchangeable.

Referring to FIG. 1A, a substrate 100 is provided. In accordance with some embodiments, the substrate 100 may be disposed on a carrier stage ST by vacuum adsorption, or a release layer (not shown) may be provided between the substrate 100 and the carrier stage ST. The release layer may be dissociated by photodissociation, thermal dissociation, another suitable method or a combination thereof. For example, depending on the dissociation method, the release layer can be matched with different types of carrier stages ST. For example, a photodissociation type release layer can be matched with a transparent glass substrate, and a thermal dissociation type release layer can be matched with a steel plate. The release layer may include, for example, ultraviolet (UV) release film, heat release tape (HRT), another suitable material, or a combination thereof. In accordance with some embodiments, the substrate 100 can serve as an interposer for integrating chips or other electronic components for subsequent packaging. In accordance with some embodiments, the substrate 100 may include a silicon substrate, a semiconductor structure substrate, a wafer, a glass substrate, a ceramic substrate, or another suitable substrate, but it is not limited thereto.

As shown in FIG. 1A, in accordance with some embodiments, a hole may be formed in the substrate 100 first. In accordance with the embodiments of the present disclosure, the hole may include a blind hole and a through hole. Here, the hole is a blind hole 100V′. The blind hole 100V′ may be formed in the substrate 100 first. The blind hole 100V′may extend from the top surface 100t to the bottom surface 100b of the substrate 100, but does not entirely penetrate the substrate 100. In other words, the bottom surface Vb′ of the blind hole 100V′ may be higher than the bottom surface 100b of the substrate 100. In accordance with some embodiments, the substrate 100 may be first subjected to a laser modification process, and then the modified substrate 100 may be removed through one or more photolithography processes and/or etching processes to form the blind hole 100V′. In accordance with some embodiments, the photolithography process may include photoresist coating (e.g., spin coating), soft baking, hard baking, mask alignment, exposure, post-exposure baking, photoresist development, cleaning and drying, etc, but it is not limited thereto. The etching process may include a dry etching process or a wet etching process, but it is not limited thereto. In accordance with some embodiments, the blind hole 100V′ may also be formed through a laser modification process.

Next, a protective layer 102 is formed on the substrate 100, and the protective layer 102 extends into the blind hole 100V′. The protective layer 102 can protect the substrate 100, improve the structural strength of the substrate 100, and reduce the risk of damaging the substrate 100 in subsequent processes. In accordance with some embodiments, the protective layer 102 may be conformally formed on the top surface 100t of the substrate 100 and the bottom surface Vb′ and the side surface Vs′ of the blind hole 100V′. The protective layer 102 may include organic materials or inorganic materials. In accordance with some embodiments, the material of the protective layer 102 may include polyimide (PI), benzocyclobutene (BCB), epoxy, polyethylene terephthalate (PET), polycarbonate (PC), polyethylene naphthalate (PEN), parylene, silicon oxide, silicon nitride, another suitable material or a combination thereof, but it is not limited thereto. In accordance with some embodiments, the protective layer 102 may be formed by a coating process, a spin coating process, a chemical vapor deposition (CVD) process, an atomic layer deposition (ALD) process, another suitable method, or a combination thereof.

Next, a conductive layer 104 is formed on the protective layer 102, and the conductive layer 104 extends into the blind hole 100V′. The conductive layer 104 can serve as a seed layer to facilitate the subsequent formation of the conductive element 106. In accordance with some embodiments, the conductive layer 104 may be conformally formed on part of the top surface 100t of the substrate 100 and the bottom surface Vb′ and side surface Vs′ of the blind hole 100V′. In accordance with some embodiments, the conductive layer 104 may include, for example, copper (Cu), titanium (Ti), aluminum (Al), molybdenum (Mo), nickel (Ni), ruthenium (Ru), tantalum (Ta), tungsten (W), nitride, carbide, another suitable conductive material or any combination of the above, but it is not limited thereto. In accordance with some embodiments, the conductive layer 104 may be a composite layer, for example, including a titanium layer and a copper layer as sub-layers, but it is not limited thereto. In accordance with some embodiments, the conductive layer 104 may be formed by a physical vapor deposition (PVD) process, an atomic layer deposition process, an electroplating process, an electroless plating process, another suitable method, or a combination thereof. In addition, the conductive layer 104 may be patterned through one or more photolithography processes and/or etching processes to define the position of the subsequently formed conductive element 106.

Next, a conductive element 106 is formed in the blind hole 100V′. The conductive element 106 may be in contact with the conductive layer 104 and electrically connected to the conductive layer 104. The conductive element 106 includes a conductive material. In accordance with some embodiments, the material of the conductive element 106 may include copper (Cu), titanium (Ti), aluminum (Al), tungsten (W), silver (Ag), gold (Au), tin (Sn), molybdenum (Mo), chromium (Cr), nickel (Ni), platinum (Pt), alloys of the aforementioned metals, another suitable material or a combination thereof, but it is not limited to thereto. In accordance with some embodiments, the conductive element 106 may be formed by a physical vapor deposition process, an electroplating process, an electroless plating process, another suitable method, or a combination thereof.

Next, a circuit structure 200 is formed on the substrate 100 and the protective layer 102, and the circuit structure 200 is electrically connected to the conductive element 106. The circuit structure 200 may be a redistribution layer (RDL), and may include at least one conductive layer 202 (only one layer is shown for convenience of explanation) and at least one insulating layer 204 (only one layer is shown for convenience of explanation). The circuit structure 200 can redistribute the circuits of the electronic device and/or further increase the circuit fan-out area, or different electronic components can be electrically connected to each other through the circuit structure 200. For example, the distance between two adjacent contact pads of the circuit structure 200 close to one end of the chip 400 may be less than or equal to the distance between two adjacent contact pads of the circuit structure 200 far away from the end of the chip 400. Therefore, the circuit structure 200 can adjust the circuit fanout conditions, but it is not limited thereto. The redistribution layer can extend a wire to a wider spacing or reroute a wire to another wire with a different spacing, and/or the redistribution layer can serve as a substrate of electrical interface route between one connection and another. For example, the pitch of two adjacent contact pads at an end of the redistribution structure that contacts the electronic component may be less than or equal to the pitch of two adjacent contact pads at the end of the redistribution structure away from the electronic component. Therefore, the redistribution structure can adjust the circuit fan-out condition or electrically connect the circuit structure/electronic component with the first pitch to the circuit structure/electronic component with the second pitch, but it is not limited thereto. Furthermore, the step of forming the redistribution layer may include providing a stack of at least one conductive layer and at least one dielectric layer. The method of forming the redistribution layer may include photolithography, etching, surface treatment, laser, electroplating, chemical plating, deposition, atomic layer deposition and other processes. Among them, surface treatment may include roughening or activating the surface of the dielectric layer or the surface of the conductive layer to improve the adhesion ability of the dielectric layer or conductive layer. For example, by increasing the surface roughness, the bonding force with subsequent film layers can be improved.

The conductive layer 202 may include conductive materials. In accordance with some embodiments, the material of the conductive layer 202 may include copper (Cu), titanium (Ti), aluminum (Al), tungsten (W), silver (Ag), gold (Au), tin (Sn), molybdenum (Mo), chromium (Cr), nickel (Ni), platinum (Pt), tantalum (Ta), alloys of the aforementioned metals, another suitable conductive material, or a combination thereof, but it is not limited thereto. In accordance with some embodiments, the conductive layer 202 may have a multi-layer structure (not shown). In accordance with some embodiments, the conductive material may be formed by an atomic layer deposition process, a physical vapor deposition process, an electroplating process, an electroless plating process, another suitable method, or a combination thereof. Furthermore, the conductive material may be patterned through one or more photolithography processes and/or etching processes to form the conductive layer 202. Moreover, in accordance with some embodiments, the material of the insulating layer 204 may include a polymer dielectric insulating material, such as polybenzoxazole (PBO), polyimide, or benzocyclobutene (BCB), another suitable polymeric dielectric material, or a combination thereof, but it is not limited thereto. In accordance with some other embodiments, the material of the insulating layer 204 may include silicon nitride, silicon oxide, silicon oxynitride, phosphosilicate glass (PSG), borosilicate glass (BSG), boron-doped phosphosilicate glass (BPSG), another suitable dielectric material, or a combination thereof, but it is not limited thereto. In accordance with some embodiments, the insulating layer 204 may be formed by a coating process, a spin coating process, a chemical vapor deposition process, a stacking process, another suitable method, or a combination thereof.

Next, a chip 400 is bonded to the circuit structure 200. In accordance with some embodiments, a connection element 302 may be formed on the circuit structure 200, and the chip 400 may be electrically connected to the circuit structure 200 through the connection element 302. Specifically, in accordance with some embodiments, the connection element 302 may be disposed corresponding to a contact pad 202u of the circuit structure 200 and a conductive element 402 of the chip 400. That is, in the normal direction of the chip 400 (e.g., the Z direction in the figure), the connection element 302 may overlap with the contact pad 202u of the circuit structure 200 and the conductive element 402 of the chip 400. In accordance with some embodiments, the chip 400 is bonded to the circuit structure 200 directly, but it is not limited to.

In accordance with some embodiments, the chip 400 may include, for example, a known-good die (KGD), an integrated circuit chip (IC), a surface mount device (SMD), a diode, a semiconductor structure, a silicon photonic chip, or another suitable electronic component, but it is not limited thereto.

In accordance with some embodiments, the material of the connection element 302 may include tin, silver, lead-free tin, copper, nickel, gold, gallium, silver, another suitable material or a combination thereof, but it is not limited thereto. In accordance with some embodiments, the connection element 302 may be bonded to the contact pad 202u of the circuit structure 200 through a reflow process, a fusion bonding process, a hybrid bonding process, a metal-to-metal bonding process, another suitable method, or a combination thereof. Thereby, the chip 400 may be bonded to the circuit structure 200.

Next, a buffer layer 304 is formed between the chip 400 and the circuit structure 200, and the buffer layer 304 is in contact with the connection element 302 and the chip 400. Furthermore, the buffer layer 304 may be in contact with the contact pad 202u of the circuit structure 200 and the conductive element 402 of the chip 400. In accordance with some embodiments, the buffer layer 304 may be partially formed on the side surface of the chip 400. The buffer layer 304 can reduce the influence of water and oxygen on the chip 400 from the external environment. In accordance with some embodiments, the buffer layer 304 may have an inclined surface, but it is not limited thereto. In accordance with some embodiments, the buffer layer 304 may include molding compound, epoxy, silicon oxide, silicon nitride, another suitable encapsulating material, or a combination thereof, but it is not limited thereto. In accordance with some embodiments, the buffer layer 304 may be formed by a compression molding process, a transfer molding process, or another suitable method. In accordance with some embodiments, the buffer layer 304 may be in a liquid or semi-liquid form during a dispensing or molding process and then solidified.

Thereafter, a first cutting step CT-1 is performed to cut the circuit structure 200 and the protective layer 102. Specifically, the first cutting step CT-1 may cut open the circuit structure 200 and the protective layer 102. Furthermore, the first cutting step CT-1 may cut a portion of the substrate 100 and form a groove 100R in the substrate 100. In other words, the first cutting step CT-1 does not entirely cut open the substrate 100, but only forms the groove 100R on the top surface 100t of the substrate 100. In accordance with some embodiments, the first cutting step CT-1 may include a laser cutting process, a knife cutting process, or a combination thereof, but it is not limited thereto. Along the normal direction of the substrate 100, a depth D of the groove may be greater than 10 μm and less than or equal to half of a thickness T100 of the substrate 100. The thickness T100 of the substrate 100 may be in a range from 50 μm to 1200 μm. With the aforementioned configuration, the crack isuuse occurred during the cutting process may be reduced.

Please refer to FIG. 1B. Next, an encapsulation layer 310 is formed to surround the chip 400, and the encapsulation layer 310 extends into the groove 100R. The encapsulation layer 310 may be in contact with the chip 400, the buffer layer 304, the circuit structure 200, the protective layer 102 and the substrate 100. In accordance with some embodiments, the encapsulation layer 310 may cover the side surfaces as well as the top surface of the chip 400. The encapsulation layer 310 can reduce the influence of water and oxygen in the external environment on the chip 400. In accordance with some embodiments, the encapsulation layer 310 may include molding compound, epoxy resin, another suitable encapsulation material, or a combination thereof, but it is not limited thereto. Furthermore, the material of the encapsulation layer 310 may be the same as or different from the material of the buffer layer 304. In accordance with some embodiments, the encapsulation layer 310 may be formed by a compression molding process, a transfer molding process, or another suitable method. In accordance with some embodiments, the encapsulation layer 310 may be in a liquid or semi-liquid form during the molding process and then solidified. In the present disclosure, the description “component A surrounds component B” means that in a cross-sectional view, component A is in contact with at least two side surfaces of component B.

Please refer to FIG. 1C. Then, the foregoing structure can be turned over, and portions of the substrate 100 away from the circuit structure 200 and the blind hole 100V′ are removed to form a through hole 100V, and the protective layer 102 and the conductive element 106 located in the through hole 100V may be exposed. In detail, in accordance with some embodiments, a thinning process may be performed on the bottom surface 100b of the substrate 100 to remove a portion of the substrate 100 and the bottom of the blind hole 100V′, thereby forming the through hole 100V penetrating the substrate 100. In accordance with some embodiments, the process of removing the substrate 100 may include removing a portion of the protective layer 102 and a portion of the conductive element 106 so that other portions of the protective layer 102 and other portions of the conductive element 106 may be disposed in the through hole 100V. As shown in FIG. 1C, the protective layer 102 and the conductive layer 104 may extend into the through hole 100V, and the conductive element 106 may be formed in the through hole 100V. In accordance with some embodiments, the thinning process may include a grinding process, a sand blasting process, a chemical-mechanical polish (CMP) process, another suitable planarization process, or a combination thereof.

It should be noted that in the aforementioned method of manufacturing an electronic device, the step of forming the circuit structure 200 is performed before the step of forming the through hole 100V, which can reduce the influence on the structures the substrate 100 and the through hole 100V by the subsequent process of forming the circuit structure 200 and reduce the risk of damaging the substrate 100 and the through hole 100V structure in subsequent processing steps.

Please continue to refer to FIG. 1D. After the thinning process, a contact pad 206 and a connection element 208 may be further formed on the substrate 100. The contact pad 206 may be disposed between the substrate 100 and the connection element 208. The contact pads 206 may be electrically connected to the conductive element 106, and the connection element 208 may be electrically connected to the conductive element 106. In accordance with some embodiments, the contact pad 206 may be disposed corresponding to the conductive element 106. That is, in the normal direction of the substrate 100 (e.g., the Z direction in the figure), the contact pad 206 may overlap the conductive element 106. In accordance with some embodiments, the connection element 208 may be disposed corresponding to contact pad 206. That is, in the normal direction of the substrate 100 (e.g., the Z direction in the figure), the connection element 208 may overlap the contact pad 206. In accordance with some embodiments, one end of the connection element 208 is electrically connected to the contact pad 206, and the other end can be electrically connected to a printed circuit board (PCB), a chip, a control component or another electronic component (not shown), but the present disclosure is not limited thereto.

In accordance with some embodiments, the contact pad 206 may include conductive materials, such as copper (Cu), titanium (Ti), aluminum (Al), tungsten (W), silver (Ag), gold (Au), tin (Sn), molybdenum (Mo), chromium (Cr), nickel (Ni), platinum (Pt), alloys of the aforementioned metals, another suitable conductive material, or a combination thereof, but it is not limited thereto. In accordance with some embodiments, the contact pads 206 may be formed by a physical vapor deposition process, an electroplating process, an electroless plating process, another suitable method, or a combination thereof. Furthermore, in accordance with some embodiments, the material of the connection element 208 may include tin, silver, lead-free tin, copper, nickel, gold, another suitable material, or a combination thereof, but it is not limited thereto. In accordance with some embodiments, the connection element 208 may be bonded to the contact pad 206 through a reflow process, a fusion bonding process, a hybrid bonding process, a metal-to-metal bonding process, another suitable method, or a combination thereof.

Next, a second cutting step CT-2 is performed to cut the substrate 100 to form an electronic unit 10U (as shown in FIG. 1D). Specifically, the second cutting step CT-2 may be performed from the bottom surface 100b of the substrate 100 to cut the substrate 100 and the encapsulation layer 310 to form separate electronic units 10U. In accordance with some embodiments, the cutting position of the second cutting step CT-2 may overlap with the groove 100R, and a recessed profile RS may be formed at the edge of the substrate 100 after cutting (as shown in FIG. 1D). Since the thickness of the substrate 100 cut by the second cutting step CT-2 is relatively thin, risks such as cracking of the substrate during the cutting process can be mitigated. In accordance with some embodiments, the second cutting step CT-2 may include a laser cutting process, a knife cutting process, or a combination thereof, but it is not limited thereto. As shown in FIG. 1D, the formed electronic unit 10U of the electronic device 10 may include a substrate 100, a through hole 100V, a protective layer 102, a conductive element 106, a circuit structure 200 and a chip 400. The through hole 100V penetrates the substrate 100. The protective layer 102 is disposed on the substrate 100, and the protective layer 102 extends into the through hole 100V. The conductive element 106 is disposed in the through hole 100V. The circuit structure 200 is disposed on the protective layer 102, and the circuit structure 200 is electrically connected to the conductive element 106. The chip 400 is bonded to the circuit structure 200. Furthermore, the substrate 100 has a recessed profile RS at the edge.

In addition, the electronic unit 10U may further include an encapsulation layer 310 surrounding the chip 400, and the encapsulation layer 310 may extend into the recessed profile RS of the substrate 100. In accordance with some embodiments, the protective layer 102 may partially extend on the top surface 100t of the substrate 100 and the side surface Vs of the through hole 100V. Furthermore, the electronic unit 10U may further include a conductive layer 104 disposed on the protective layer 102. The conductive layer 104 may extend into the through hole 100V, and the conductive layer 104 may be electrically connected to the circuit structure 200. Specifically, the conductive layer 104 may be electrically connected to the circuit structure 200 through the conductive element 106.

In addition, the circuit structure 200 may include at least one conductive layer 202 and at least one insulating layer 204. In accordance with some embodiments, the insulating layer 204 may include a tilted side surface, and in a cross-sectional view, the insulating layer 204 may include an arcuate or curved top corner.

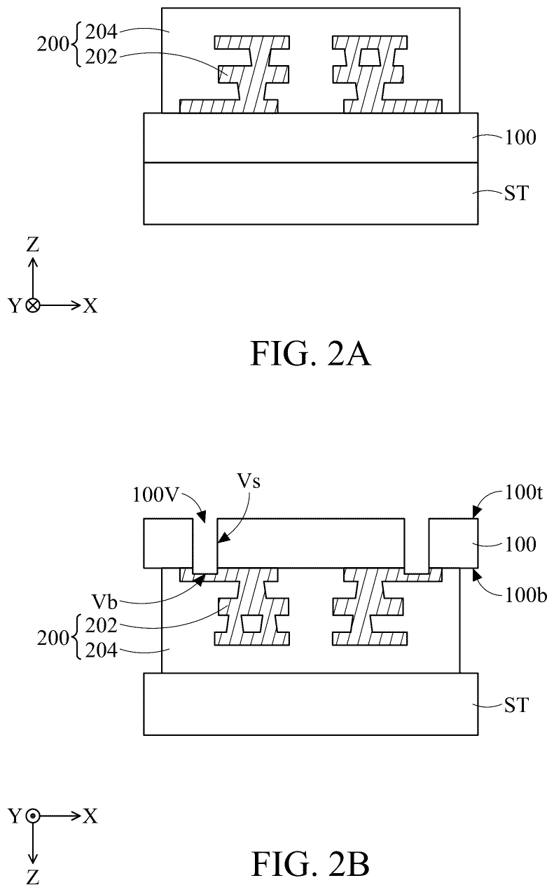

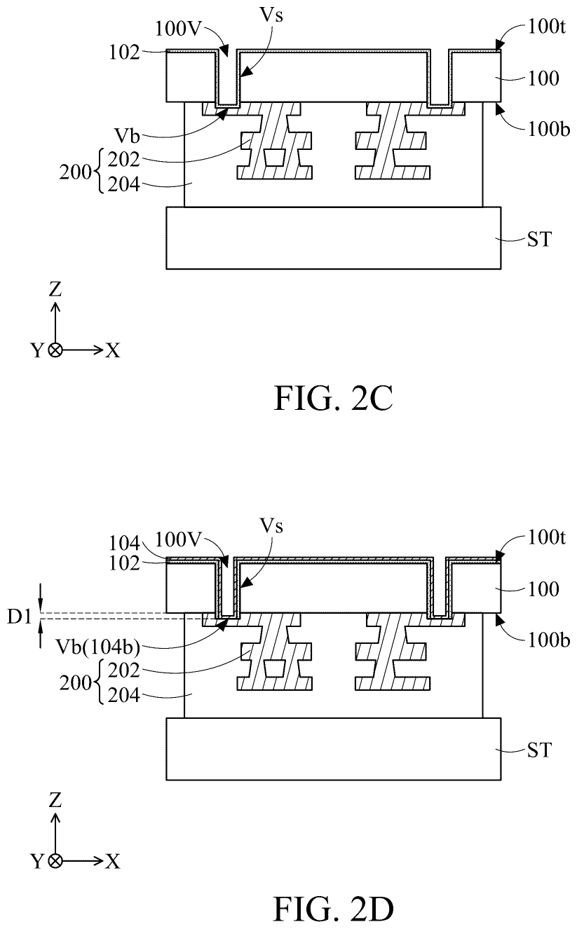

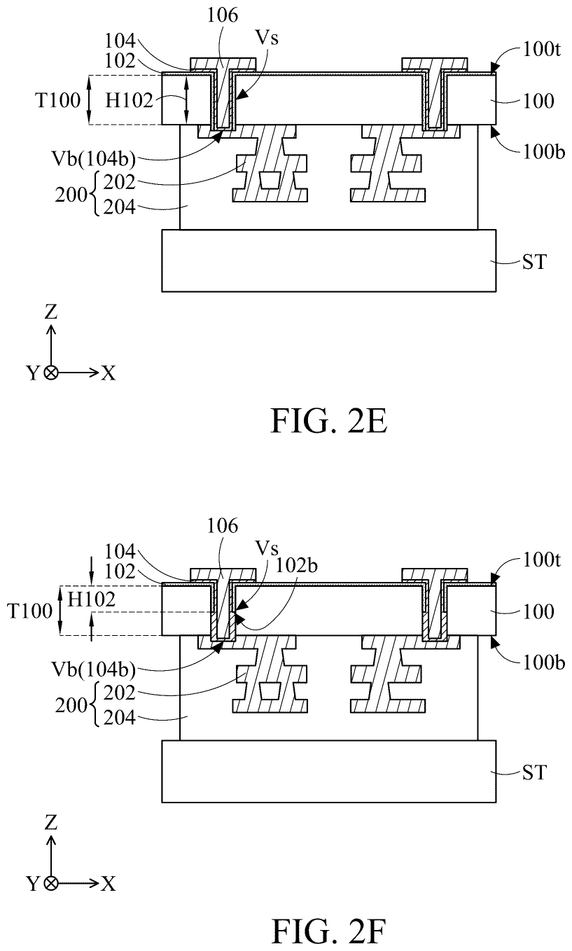

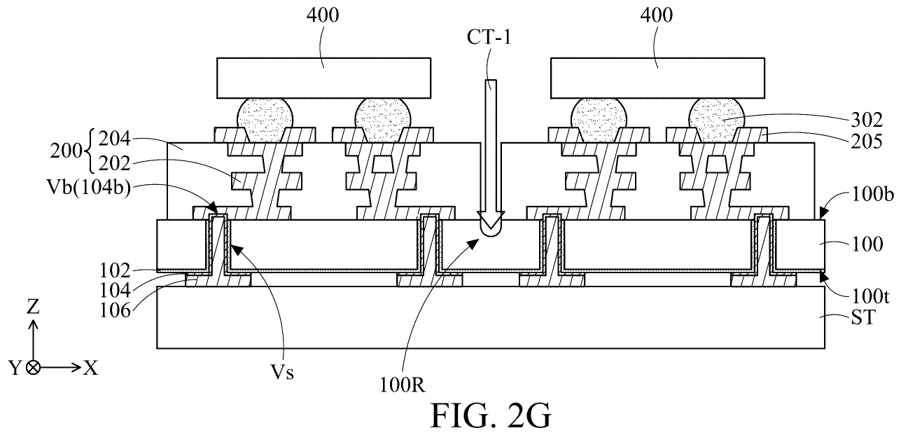

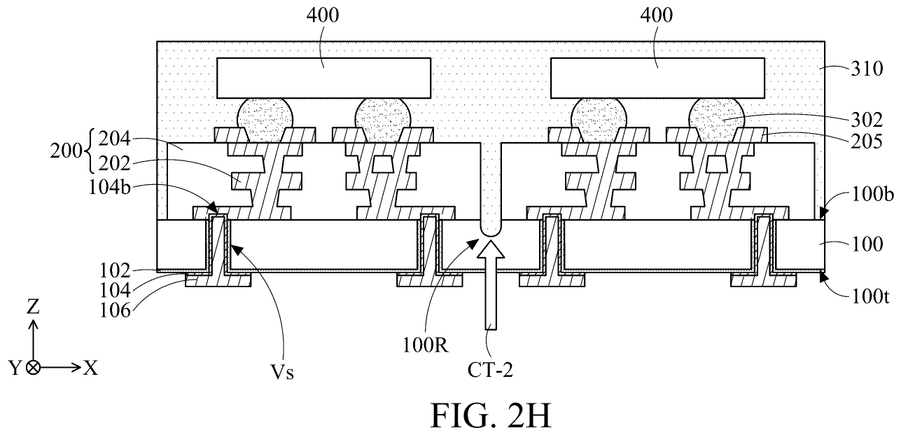

Please refer to FIGS. 2A to 2H, which are cross-sectional diagrams of the electronic device 10 in different stages of the manufacturing process in accordance with some other embodiments of the present disclosure. For clear explanation, some components of the electronic device 10 may be omitted in the drawings, and only some components are schematically illustrated. In accordance with some embodiments, additional features may be added to the electronic device 10 described below. In accordance with some embodiments, additional operating steps may be provided before, during, and/or after the method of manufacturing the electronic device 10. In accordance with some embodiments, some of the operation steps described may be replaced or omitted, and the order of some of the operation steps described may be interchangeable. In addition, it should be understood that components or elements that are the same as or similar to those mentioned above will be denoted by the same or similar numerals, and their materials and functions are the same or similar to those described above, and thus will not be repeated in the following description.

Referring to FIG. 2A, the substrate 100 is provided. In accordance with some embodiments, the substrate 100 may be placed on the carrier stage ST. Then, the circuit structure 200 can be formed on the substrate 100. As mentioned above, the circuit structure 200 may be a redistribution layer (RDL), and may include at least one conductive layer 202 and at least one insulating layer 204.

Referring to FIG. 2B, the aforementioned structure can be turned over and placed on the carrier stage ST so that the substrate 100 is located above the circuit structure 200. Next, a hole may be formed in the substrate. In accordance with the embodiments of the present disclosure, the hole may include a blind hole and a through hole. Here, the hole is a through hole 100V that penetrates the substrate 100. The through hole 100V may extend from the top surface 100t of the substrate 100 toward the bottom surface 100b and penetrate the substrate 100. In accordance with some embodiments, the through hole 100V may extend into the circuit structure 200, for example, may expose a portion of the conductive layer 202. In other words, the bottom surface Vb of the through hole 100V may be lower than the bottom surface 100b of the substrate 100. In accordance with some embodiments, the substrate 100 may be first subjected to a laser modification process, and then the modified substrate 100 may be removed through one or more photolithography processes and/or etching processes to form the through hole 100V. In accordance with some embodiments, the aforementioned photolithography process and/or etching process may also remove a portion of the circuit structure 200 (e.g., the conductive layer 202).

It should be noted that in the aforementioned method of manufacturing an electronic device, the step of forming the circuit structure 200 is performed before the step of forming the through hole 100V, which can reduce the influence on the structures the substrate 100 and the through hole 100V by the subsequent process of forming the circuit structure 200 and reduce the risk of damaging the substrate 100 and the through hole 100V structure in subsequent processing steps.

Please refer to FIG. 2C. Next, the protective layer 102 is formed on the substrate 100, and the protective layer 102 extends into the through hole 100V. The protective layer 102 can protect the substrate 100, maintain the structural strength of the substrate 100 and the through hole 100V, and reduce the risk of damaging the substrate 100 and the through hole 100V in subsequent processes. In accordance with some embodiments, the protective layer 102 may be conformally formed on the top surface 100t of the substrate 100 and the bottom surface Vb and side surface Vs of the through hole 100V. In accordance with some embodiments, the protective layer 102 may also partially extend into the circuit structure 200, for example, contacting a portion of the conductive layer 202.

Please refer to FIG. 2D. Next, a portion of the protective layer 102 located in the through hole 100V is removed to expose the circuit structure 200. Specifically, the protective layer 102 located on the bottom surface Vb of the through hole 100V may be removed to expose a portion of the conductive layer 202 of the circuit structure 200. In accordance with some embodiments, the step of removing a portion of the protective layer 102 located in the through hole 100V may also remove a portion of the circuit structure 200 such that a surface of the circuit structure 200 exposed by the through hole 100V is non-coplanar with the bottom surface 100b of the substrate 100. The bottom suface 100b refers to the surface of the substrate 100 close to the circuit structure 200. In accordance with some embodiments, the protective layer 102 in the through hole 100V may be removed through one or more photolithography processes and/or etching processes.

Next, the conductive layer 104 is formed on the protective layer 102, the conductive layer 104 extends into the through hole 100V, and the conductive layer 104 is electrically connected to the circuit structure 200. In accordance with some embodiments, the conductive layer 104 may be conformally formed on the protective layer 102 and the bottom surface Vb of the through hole 100V, and the conductive layer 104 may contact and be electrically connected to the conductive layer 202 of the circuit structure 200. In accordance with some embodiments, the conductive layer 104 may extend into the circuit structure 200 such that the bottom surface 104b of the conductive layer 104 is non-coplanar with the bottom surface 100b of the substrate 100, and the bottom surface 100b refers to the surface of the substrate 100 close to the circuit structure 200. The bottom surface 104b of the conductive layer 104 may be lower than the bottom surface 100b of the substrate 100. As shown in FIG. 2D, in accordance with some embodiments, the bottom surface 104b of the conductive layer 104 located in the through hole 100V and the bottom surface 100b of the substrate 100 are separated by a distance D1, and the distance D1 may be between 0.001micrometers and 0.5 micrometers. The aforementioned distance D1 refers to the minimum distance between the bottom surface 104b of the conductive layer 104 and the bottom surface 100b of the substrate 100 in the normal direction of the substrate 100.

Please refer to FIG. 2E. Next, the conductive element 106 is formed in the through hole 100V. The conductive element 106 may be formed on the conductive layer 104 and be in contact with and electrically connected to the conductive layer 104. In accordance with some embodiments, the conductive element 106 may also partially extend into the circuit structure 200, and a portion of the conductive element 106 may be disposed on the top surface 100t of the substrate 100.

As shown in FIG. 2E, in accordance with some embodiments, the height H102 of the protective layer 102 extending in the through hole 100V may be greater than or equal to one-fifth of the thickness T100 of the substrate 100 and less than or equal to four-fifths of the thickness T100 of the substrate 100 (that is, ⅘×thickness T100≥height H102≥⅕ thickness T100). For example, the height H102 of the protective layer 102 extending in the through hole 100V is substantially the same as the thickness T100 of the substrate 100. The aforementioned height H102 refers to the maximum height of the protective layer 102 in the through hole 100V in the normal direction of the substrate 100 (for example, the Z direction in the figure). The aforementioned thickness T100 refers to the maximum thickness of the substrate 100 in the normal direction of the substrate 100 (for example, the Z direction in the drawing). Through the aforementioned configuration of the protective layer 102, sufficient protection effect can be provided for the substrate 100 and the through hole 100V.

Please refer to FIG. 2F, which is a cross-sectional diagram of an electronic device in different stages of the manufacturing process in accordance with some other embodiments of the present disclosure. As shown in FIG. 2F, in accordance with some other embodiments, the step of removing a portion of the protective layer 102 located in the through hole 100V includes removing a portion of the protective layer 102 located on the bottom surface Vb and the surfaces of portions of the circuit structure 200. In this embodiment, the bottom surface 102b of the protective layer 102 may be higher than the bottom surface 100b of the substrate 100, and the bottom surface 102b of the protective layer 102 is not aligned with the bottom surface 104b of the conductive layer 104. Furthermore, the height H102 of the protective layer 102 extending in the through hole 100V may be also greater than or equal to one-fifth of the thickness T100 of the substrate 100 (that is, the height H102≥⅕×the thickness T100). For example, the height H102 of the protective layer 102 extending to in the through hole 100V may be greater than or equal to one quarter, one third, or one half of the thickness T100 of the substrate 100. Through the aforementioned configuration of the protective layer 102, sufficient protection effect can be provided for the substrate 100 and the through hole 100V.

Please refer to FIG. 2G, which is a schematic diagram showing the subsequent manufacturing process with the structure shown in FIG. 2E. It should be understood that FIG. 2E only illustrates the partial structure of the electronic device, and FIG. 2G is the schematic diagram showing the repeating units including the partial structure being subsequently subjected to the packaging process.

As shown in FIG. 2G, the aforementioned structure can be turned over and placed on the carrier stage ST so that the circuit structure 200 is located above the substrate 100. Then, the chip 400 is bonded to the circuit structure 200. In detail, in accordance with some embodiments, the circuit structure 200 may be thinned first to expose the conductive layer 202. Then, a contact pad 205 and a connection element 302 may be formed on the circuit structure 200. The chip 400 may be electrically connected to the circuit structure 200 through the connection element 302. Specifically, in accordance with some embodiments, the connection element 302 may be disposed corresponding to the contact pad 205 of the circuit structure 200 and the chip 400. That is, in the normal direction of the chip 400 (e.g., the Z direction in the figure), the connection element 302 may overlap the contact pad 205 and the chip 400.

Thereafter, the first cutting step CT-1 is performed to cut the circuit structure 200. In detail, the first cutting step CT-1 may cut open the circuit structure 200. Furthermore, the first cutting step CT-1 may cut a portion of the substrate 100 and form a groove 100R in the substrate 100. In other words, the first cutting step CT-1 does not entirely cut open the substrate 100, but only forms the groove 100R on the top surface 100t of the substrate 100. In accordance with some embodiments, the first cutting step CT-1 may include a laser cutting process, a knife cutting process, or a combination thereof, but it is not limited thereto.

Please refer to FIG. 2H. Next, the encapsulation layer 310 is formed to surround the chip 400, and the encapsulation layer 310 extends into the groove 100R. The encapsulation layer 310 may be in contact with the chip 400, the contact pad 205, the connection element 302, the circuit structure 200 and the substrate 100. In accordance with some embodiments, the encapsulation layer 310 may cover the side surfaces as well as the top surface of the chip 400. The encapsulation layer 310 can reduce the influence of water and oxygen in the external environment on the chip 400.

Next, the second cutting step CT-2 is performed to cut the substrate 100 to form the electronic unit 10U (not labeled). In detail, the second cutting step CT-2 may be performed from the bottom surface 100t of the substrate 100 to cut open the substrate 100, the protective layer 102 and the encapsulation layer 310 to form the separate electronic unit 10U (not labeled). In accordance with some embodiments, the cutting position of the second cutting step CT-2 may overlap with the groove 100R, and a recessed profile RS may be formed at the edge of the substrate 100 after cutting (as shown in FIG. 1D). Since the thickness of the substrate 100 cut by the second cutting step CT-2 is relatively thin, risks such as cracking of the substrate during the cutting process can be mitigated.

In accordance with some embodiments, the connection element (not shown) may be further formed corresponding to the conductive element 106, so that one end of the connection element is electrically connected to the conductive element 106, and the other end is electrically connected to the printed circuit board, chip, control element or another electronic component (not shown), but the present disclosure is not limited thereto.

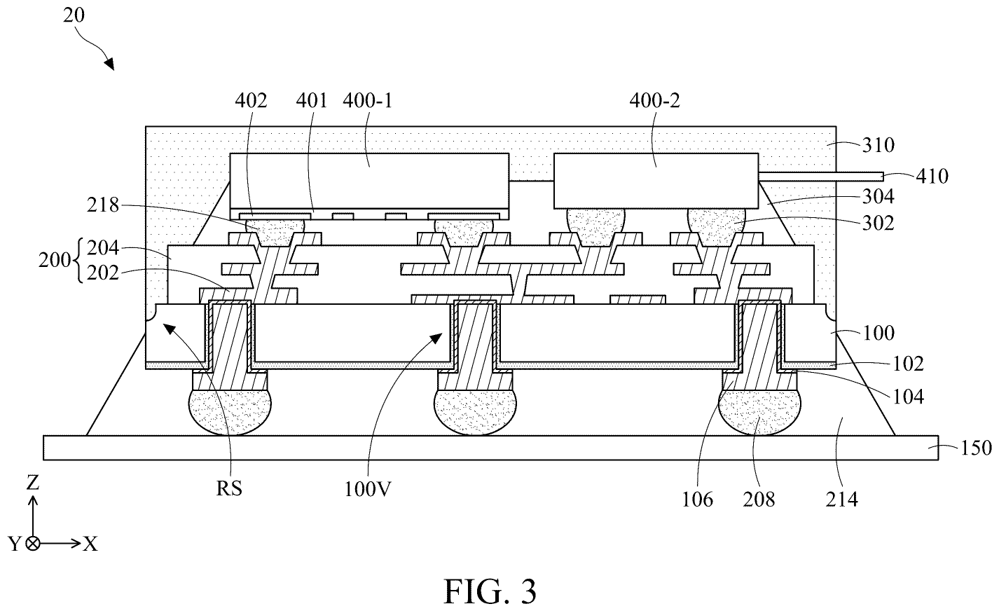

Please refer to FIG. 3, which is a cross-sectional diagram of an electronic device 20 in accordance with some embodiments of the present disclosure. For clear explanation, some components of the electronic device 20 may be omitted in the drawings, and only some components are schematically illustrated. In accordance with some embodiments, additional features may be added to the electronic device 20 described below.

The electronic device 20 may be formed based on the aforementioned method of manufacturing the electronic device and combined with a suitable packaging method. For example, the electronic device 20 may be applied to co-packaged optics (CPO), but the present disclosure is not limited thereto.

As shown in FIG. 3, the electronic device 20 includes a substrate 100, a through hole 100V, a protective layer 102, a conductive element 106, a circuit structure 200 and a chip 400. The through hole 100V penetrates the substrate 100. The protective layer 102 is disposed on the substrate 100, and the protective layer 102 extends into the through hole 100V. The conductive element 106 is disposed in the through hole 100V. The circuit structure 200 is disposed on the protective layer 102, and the circuit structure 200 is electrically connected to the conductive element 106. The chip 400 is bonded to the circuit structure 200. Furthermore, the substrate 100 has a recessed profile RS at the edge.

In addition, the electronic device 20 may further include an encapsulation layer 310 surrounding the chip 400, and the encapsulation layer 310 extends into the recessed profile RS of the substrate 100. In accordance with some embodiments, the protective layer 102 may partially extend on the top surface 100t of the substrate 100 and the side surface Vs of the through hole 100V. Furthermore, the electronic device 20 may further include a conductive layer 104 disposed on the protective layer 102. The conductive layer 104 may extend into the through hole 100V. The conductive layer 104 may be electrically connected to the circuit structure 200. Specifically, the conductive layer 104 can be electrically connected to the circuit structure 200 through the conductive element 106. In accordance with some embodiments, the conductive layer 104 may extend into circuit structure 200 and contact the conductive layer 202.

In addition, the electronic device 20 may further include a connection element 208. The connection element 208 may be disposed corresponding to the conductive element 106. That is, in the normal direction of the substrate 100 (for example, the Z direction in the figure), the connection element 208 may overlap conductive element 106. One end of the connection element 208 may be electrically connected to the conductive element 106, and the other end may be electrically connected to an electronic component 150. The electronic component 150 may be, for example, a printed circuit board, but it is not limited thereto. In addition, a buffer layer 214 may be further formed between the electronic component 150 and the substrate 100, and the buffer layer 214 may be in contact with the conductive element 106 and the connection element 208. In accordance with some embodiments, the buffer layer 214 may be partially formed on the side surface of the substrate 100. The buffer layer 214 can reduce the influence of water and oxygen in the external environment on the conductive element 106 and the connection element 208 and maintain the quality of electrical connection.

In addition, as shown in FIG. 3, the electronic device 20 may include several chips. For example, the circuit structure 200 may be electrically connected to a chip 400-1 through the connection element 218, and may be electrically connected to a chip 400-2 through the connection element 302. In detail, the connection element 218 may be disposed corresponding to the contact pad (not labeled) of the circuit structure 200 and the conductive element 402 of the chip 400-1. In accordance with some embodiments, a passivation layer 401 of the chip 400-1 may expose the conductive element 402. In the normal direction of the chip 400-1 (e.g., the Z direction in the figure), the connection element 218 may at least partially overlap the conductive element 402 and the passivation layer 401. In accordance with some embodiments, the chip 400-1 may include, for example, a known good wafer (KGD), an integrated circuit wafer (IC), a surface mount device (SMD), a diode chip, or another suitable electronic component, but is it is not limited thereto. Furthermore, in accordance with some embodiments, the chip 400-2 may include, for example, a photonic integrated circuit (PIC), which may be connected to an optical fiber 410 for transmitting and processing optical signals. Based on the above, the electronic device 20 can co-package the optical chip module and the electronic chip module together to form a co-packaged optical element (CPO).

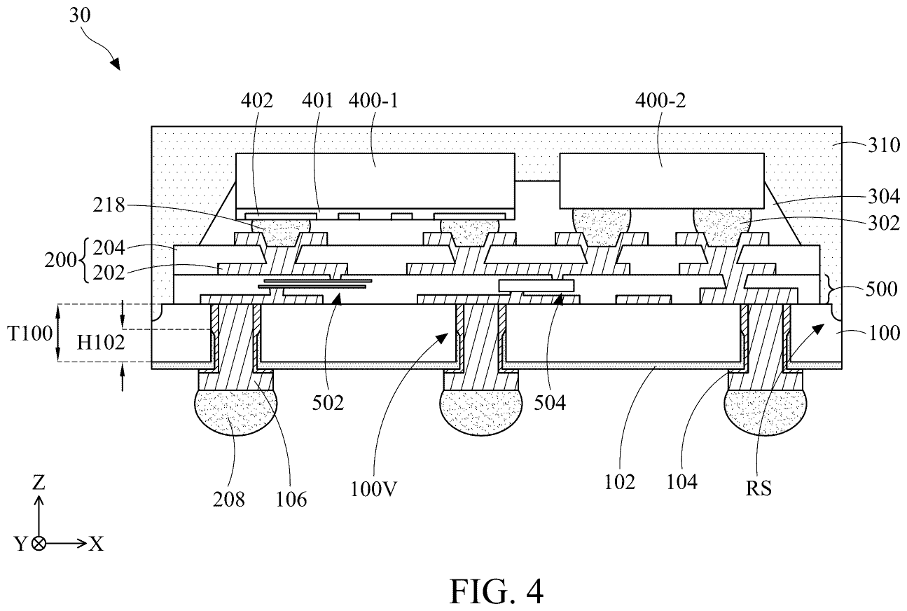

Please refer to FIG. 4, which is a cross-sectional diagram of an electronic device 30 in accordance with some embodiments of the present disclosure. For clear explanation, some components of the electronic device 30 may be omitted in the drawings, and only some components are schematically illustrated. In accordance with some embodiments, additional features may be added to the electronic device 30 described below.

Similarly, the electronic device 30 includes a substrate 100, a through hole 100V, a protective layer 102, a conductive element 106, a circuit structure 200, and a chip 400. The through hole 100V penetrates the substrate 100. The protective layer 102 is disposed on the substrate 100, and the protective layer 102 extends into the through hole 100V. The conductive element 106 is disposed in the through hole 100V. The circuit structure 200 is disposed on the protective layer 102, and the circuit structure 200 is electrically connected to the conductive element 106. The chip 400 is bonded to the circuit structure 200. Furthermore, the substrate 100 has a recessed profile RS at the edge.

In addition, the electronic device 30 may further include an encapsulation layer 310 surrounding the chip 400, and the encapsulation layer 310 extends into the recessed profile RS of the substrate 100. In accordance with some embodiments, the protective layer 102 may partially extend on the top surface 100t of the substrate 100 and the side surface Vs of the through hole 100V. In this embodiment, the protective layer 102 located on the bottom surface and side surface of the through hole 100V is also partially removed, and the height H102 of the protective layer 102 extending in the through hole 100V is greater than or equal to one-fifth of the thickness T100 of the substrate 100 (that is, height H102≥⅕×thickness T100). For example, the height H102 of the protective layer 102 extending in the through hole 100V may be greater than or equal to one quarter, one third, or one half of the thickness T100 of the substrate 100. Furthermore, the electronic device 20 may further include a conductive layer 104 disposed on the protective layer 102. The conductive layer 104 may extend into the through hole 100V, and the conductive layer 104 may be electrically connected to the circuit structure 200. Specifically, the conductive layer 104 may be electrically connected to the circuit structure 200 through the conductive element 106. In accordance with some embodiments, conductive layer 104 may extend into circuit structure 200 and contact conductive layer 202.

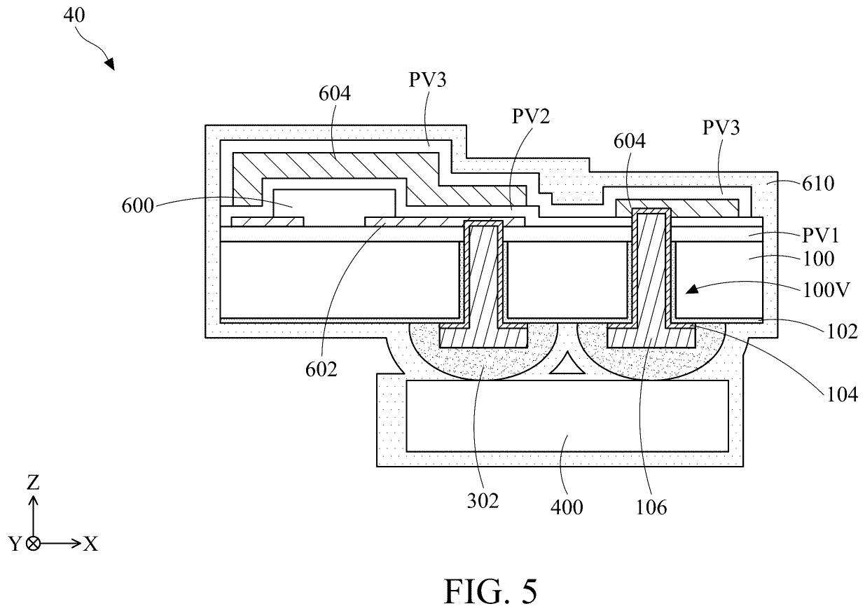

In addition, as shown in FIG. 4, the electronic device 30 may further include an integrated component structure 500. The integrated component structure 500 may be disposed between the substrate 100 and the circuit structure 200, and the integrated component structure 500 may be electrically connected to the conductive element 106 and the circuit structure 200. In accordance with some embodiments, the integrated component structure 500 may include a passive component 502, an active component 504, or another suitable electronic component. For example, the active component 502 may include a thin-film transistor, and the passive component 504 may include a capacitor, a resistor, or an inductor, but the present disclosure is not limited thereto. In accordance with some embodiments, the signal transmission path or signal loss between electronic components in the packaging structure can be reduced by the integrated component structure 500. Please refer to FIG. 5, which is a cross-sectional diagram of an electronic device 40 in accordance with some embodiments of the present disclosure. For clear explanation, some components of the electronic device 40 may be omitted in the drawings, and only some components are schematically illustrated. In accordance with some embodiments, additional features may be added to the electronic device 40 described below.

The electronic device 40 may be formed based on the aforementioned method of manufacturing the electronic device and combined with a suitable packaging method. For example, the electronic device 40 may be applied in an antenna package (Antenna in Package, AiP), but the present disclosure is not limited thereto.

As shown in FIG. 5, the electronic device 40 may include a substrate 100, a through hole 100V, a protective layer 102, a conductive element 106, and a chip 400. In this embodiment, the circuit structure may include a thin-film transistor 600, a first conductive layer 602, a second conductive layer 604, a first passivation layer PV1, a second passivation layer PV2, and a third passivation layer PV3. The first conductive layer 602 may be electrically connected to a scan line or a data line, and the second conductive layer 604 may be electrically connected to a ground signal line or a common voltage signal line, but it is not limited thereto. Specifically, in accordance with some embodiments, the first passivation layer PV1 may be formed on the substrate 100, the first conductive layer 602 and the thin-film transistor 600 may be formed on the first passivation layer PV1, and the first conductive layer 602 may be electrically connected to the thin-film transistor 600. Then, the second passivation layer PV2 may be formed on the first conductive layer 602 and the thin-film transistor 600, and the second conductive layer 604 may be formed on the first passivation layer PV1 and the second passivation layer PV2. After that, a third passivation layer PV3 may be formed on the second conductive layer 604.

In accordance with some embodiments, the materials and manufacturing methods of the first conductive layer 602 and the second conductive layer 604 may be the same as or similar to the aforementioned conductive element 106, and thus will not be repeated here. In accordance with some embodiments, the first passivation layer PV1, the second passivation layer PV2, and the third passivation layer PV3 may include inorganic materials, organic materials, or a combination thereof, but it is not limited thereto. For example, the inorganic material may include silicon nitride, silicon oxide, silicon oxynitride, another suitable material, or a combination thereof, but it is not limited thereto. For example, the organic material may include polyethylene terephthalate (PET), polyethylene (PE), polyethersulfone (PES), polycarbonate (PC), polymethylmethacrylate (PMMA), polyimide (PI), photosensitive polyimide (PSPI), benzocyclobutene (BCB), another suitable passivation material or a combination thereof, but it is not limited thereto. In accordance with some embodiments, the first passivation layer PV1, the second passivation layer PV2, and the third passivation layer PV3 may be formed by a coating process, a spin coating process, a chemical vapor deposition process, another suitable method, or a combination thereof.

As shown in FIG. 5, the through hole 100V penetrates the substrate 100 and the first passivation layer PV1. The protective layer 102 is disposed on the substrate 100, and the protective layer 102 extends into the through hole 100V. The conductive element 106 is disposed in the through hole 100V, and the conductive element 106 may be electrically connected to the first conductive layer 602 and the second conductive layer 604. In addition, the conductive element 106 may be electrically connected to the chip 400 through the connection element 302. Specifically, the connection element 302 may be disposed corresponding to the conductive element 106 and the chip 400. That is, in the normal direction of the chip 400 (for example, the Z direction in the figure), the connection element 302 may at least partially overlap the conductive element 106 and the chip 400. In this embodiment, the chip 400 may include a varactor diode, but it is not limited thereto. Furthermore, the chip 400 may be bonded to the connection element 302 in the form of a chip on board (COB) package.

In addition, the electronic device 40 may further include an encapsulation layer 610. The encapsulation layer 610 may surround the chip 400, the substrate 100, the connection element 302, the first passivation layer PV1, the second passivation layer PV2, and the third passivation layer PV3. In accordance with some embodiments, the material and manufacturing method of the encapsulation layer 610 may be the same as or similar to the aforementioned encapsulation layer 310, and thus will not be repeated here.

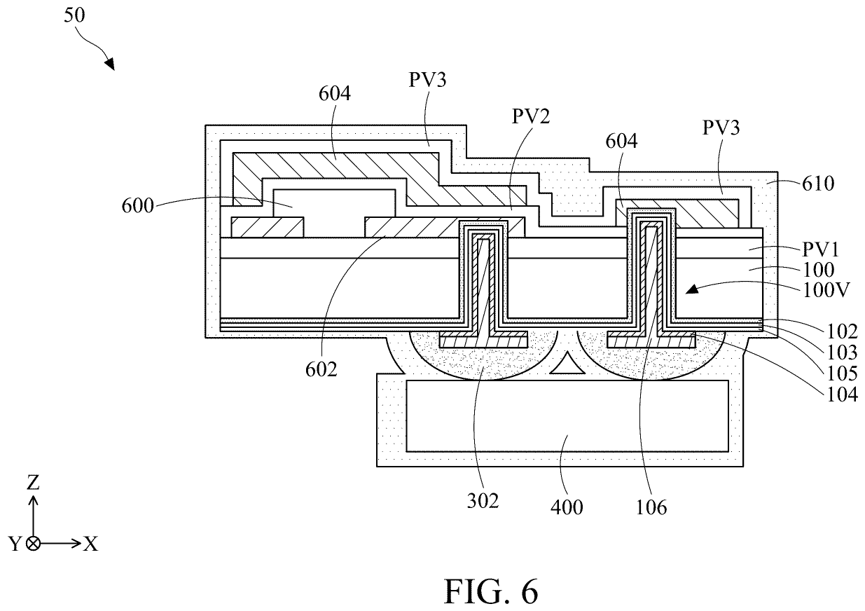

Please refer to FIG. 6, which is a cross-sectional diagram of an electronic device 50 in accordance with some embodiments of the present disclosure. For clear explanation, some components of the electronic device 50 may be omitted in the drawings, and only some components are schematically illustrated. In accordance with some embodiments, additional features may be added to the electronic device 50 described below.

Compared with the electronic device 40 shown in FIG. 5, the electronic device 50 further includes a metal layer 103 and a dielectric layer 105. The metal layer 103 may be disposed in the through hole 100V. The dielectric layer 105 may be disposed on the metal layer 103. The conductive layer 104 may be disposed on the dielectric layer 105. The conductive layer 104 may extend into the through hole 100V. The conductive element 106 may be disposed on the conductive layer 104. In detail, after forming the protective layer 102 on the substrate 100 and in the through hole 100V, the metal layer 103 may be formed in the through hole 100V. The dielectric layer 105 may be formed on the metal layer 103. The conductive layer 104 may be formed on the dielectric layer 105, and the conductive layer 104 may extend into the through hole 100V. In accordance with some embodiments, the metal layer 103 and the dielectric layer 105 may be conformally formed on the surface of the substrate 100 and in the through hole 100V. The metal layer 103 may be electrically connected to the ground signal. Through the above-mentioned configuration of the metal layer 103 and the dielectric layer 105, the occurrence of signal shielding and mutual interference caused by conductive materials in adjacent through holes 100V can be reduced, which has the effect of electromagnetic interference (EMI) shielding.

In accordance with some embodiments, the material of the metal layer 103 may include copper (Cu), titanium (Ti), aluminum (Al), tungsten (W), silver (Ag), gold (Au), tin (Sn), molybdenum (Mo), chromium (Cr), nickel (Ni), platinum (Pt), tantalum (Ta), alloys of the aforementioned metals, another suitable conductive material, or a combination thereof, but it is not limited thereto. In accordance with some embodiments, the metal layer 103 may be formed by an atomic layer deposition process, a physical vapor deposition process, an electroplating process, an electroless plating process, another suitable method, or a combination thereof. Furthermore, in accordance with some embodiments, the dielectric layer 105 may include a low dielectric constant material. In accordance with some embodiments, the dielectric layer 105 may be formed by a coating process, a spin coating process, a chemical vapor deposition process, another suitable method, or a combination thereof.

To summarize the above, in accordance with the embodiments of the present disclosure, the method of manufacturing an electronic device provided can improve the process yield of forming through holes in a substrate (for example, an interposer substrate). For example, the structural strength of the substrate and the quality of the electrical connection between the circuit and the conductive elements, etc. can be improved during the process. The reliability and overall performance of the packaging structure of the electronic device thereby can be improved.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. A method of manufacturing an electronic device, comprising:
providing a substrate;
forming a circuit structure on the substrate;
forming a hole in the substrate;
forming a conductive element in the hole;
bonding a chip to the circuit structure; and
performing a first cutting step to cut the circuit structure and a portion of the substrate, and forming a groove in the substrate.

2. The method of manufacturing an electronic device as claimed in claim 1, further comprising:
forming an encapsulation layer surrounding the chip, wherein the encapsulation layer extends into the groove.

3. The method of manufacturing an electronic device as claimed in claim 1, wherein the step of forming the hole in the substrate comprises forming a through hole penetrating the substrate, and the step of forming the through hole comprises:
forming a blind hole in the substrate;
forming a protective layer on the substrate, wherein the protective layer extends into the blind hole; and
removing portions of the substrate and the blind hole to form the through hole, wherein the protective layer and the conductive element located in the through hole are exposed.

4. The method of manufacturing an electronic device as claimed in claim 1, further comprising:
performing a second cutting step to cut the substrate to form an electronic unit.

5. The method of manufacturing an electronic device as claimed in claim 1, wherein the step of forming the circuit structure is performed before the step of forming the through hole.

6. The method of manufacturing an electronic device as claimed in claim 5, further comprising:
forming a protective layer on the substrate, wherein the protective layer extends into the through hole and contacts at least a portion of the circuit structure.

7. The method of manufacturing an electronic device as claimed in claim 6, further comprising:
removing a portion of the protective layer located in the through hole to expose the circuit structure.

8. The method of manufacturing an electronic device as claimed in claim 7, further comprising:
forming a conductive layer on the protective layer, wherein the conductive layer extends into the through hole, and the conductive layer is electrically connected to the circuit structure.

9. The method of manufacturing an electronic device as claimed in claim 7, wherein the step of removing the portion of the protective layer located in the through hole also removes a portion of the circuit structure, so that a surface of the circuit structure exposed by the through hole is non-coplanar with a surface of the substrate.

10. The method of manufacturing an electronic device as claimed in claim 7, wherein the step of removing the portion of the protective layer located in the through hole comprises removing the portion of the protective layer located on a bottom surface and a side surface of the portion of the circuit structure.

11. The method of manufacturing an electronic device as claimed in claim 1, wherein a height of the protective layer extending into the through hole is greater than or equal to one-fifth of a thickness of the substrate and less than or equal to four-fifths of the thickness of the substrate.

12. The method of manufacturing an electronic device as claimed in claim 3, wherein after the step of forming the through hole penetrating the substrate, the method further comprises:
forming a metal layer in the through hole;
forming a dielectric layer on the metal layer; and
forming a conductive layer on the dielectric layer, wherein the conductive layer extends into the through hole.

13. An electronic device, comprising:
a substrate;
a through hole penetrating the substrate;
a protective layer disposed on the substrate, wherein the protective layer extends into the through hole;
a conductive element disposed in the through hole;
a circuit structure disposed on the protective layer, wherein the circuit structure is electrically connected to the conductive element;
a chip bonded to the circuit structure, wherein the substrate has a recessed profile at an edge.

14. The electronic device as claimed in claim 13, further comprising:
an encapsulation layer surrounding the die, wherein the encapsulation layer extends into the recessed profile.

15. The electronic device as claimed in claim 13, wherein the protective layer partially extends on a top surface of the substrate and a side surface of the through hole.

16. The electronic device as claimed in claim 15, wherein a height of the protective layer extending in the through hole is greater than or equal to one-fifth of a thickness of the substrate and less than or equal to four-fifths of the thickness of the substrate.

17. The electronic device as claimed in claim 13, further comprising:
a conductive layer disposed on the protective layer, wherein the conductive layer extends into the through hole, and the conductive layer is electrically connected to the circuit structure.

18. The electronic device as claimed in claim 17, wherein the conductive layer extends into the circuit structure so that a bottom surface of the conductive layer is non-coplanar with a bottom surface of the substrate.

19. The electronic device as claimed in claim 13, further comprising:
a metal layer disposed in the through hole;
a dielectric layer disposed on the metal layer; and
a conductive layer disposed on the dielectric layer, wherein the conductive layer extends into the through hole, and the conductive element is disposed on the conductive layer.

20. The electronic device as claimed in claim 13, further comprising:
an integrated component structure disposed between the substrate and the circuit structure, and electrically connected to the conductive element and the circuit structure.
